(19) United States
(12) Patent Application Publication
(10) Pub. No.: US 2022/0084146 A1
(43) Pub. Date: Mar. 17, 2022

(54) SYSTEM AND METHOD FOR EVALUATING AND OPTIMIZING LAND USE

(71) Applicant: STRATIFYX, INC., Solvang, CA (US)

(72) Inventors: Lewis K. Eisaguirre, Solvang, CA (US); Steven I. Apfelbaum, Solvang, CA (US); Gatlin D. Fenwick, Solvang, CA (US)

(73) Assignee: STRATIFYX, INC.

(21) Appl. No.: 17/471,699

(22) Filed: Sep. 10, 2021

Related U.S. Application Data
(60) Provisional application No. 62/706,807, filed on Sep. 11, 2020.

(51) Int. Cl. G06Q 50/16; G06Q 30/00; G06F 30/13

(52) U.S. Cl. CPC G06Q 50/165; G06F 30/13; G06Q 30/018

(57) ABSTRACT

A system for determining a set of potential land uses for a land parcel is provided. The system includes a processing device having a transmitting/receiving element configured to receive attributes of the land parcel, governmental restrictions, environmental impact data, natural resource market pricing, and applicable land use restrictions and requirements for the land parcel and a processor configured to spatially map the at least one real property into a three dimensional representation including at least surface and sub-surface attributes of the land parcel, determine potential land uses for the land parcel based on available information relevant to the land parcel, and assign present values to the potential land uses. The processing device provides a number of potential land uses and assigned present values for the land parcel determined by the processor to a requesting entity.

The present application claims priority based on U.S. Provisional Patent Application Ser. No. 62/706,807, entitled “Method and software data processing system of natural resource inventory layer stratification, legal rights bundling, predictive valuation and open natural resource rights market for optimized land use,” inventors Lewis K. Eisaguirre, et al., filed Sep. 11, 2020, the entirety of which is incorporated herein by reference.

### BACKGROUND OF THE INVENTION

### Field of the Invention

The present invention relates generally to optimization of land use, and more specifically to natural resource inventory layer stratification, legal rights bundling, predictive valuation and operation of an open natural resource rights market for optimized land use.

### Description of the Related Art

A number of methods have been developed to determine how land can be best used while concurrently developing and utilizing natural resources. Some solutions attempt to use market valuations and others utilize subjective societal values. These solutions generally evaluate only a portion or subset of the potential natural resources available on a given tract of land. These solutions fail to meet the needs of natural resource owners and society in general because they do not result in a clear relative valuation of what the best use of the land is from an economic perspective, both for the land owner and society. As a result, land and natural resources on the land are developed or utilized in a manner that is inefficient and can be detrimental to the productive use of such land. In many situations, climate change impacts are exacerbated.

Certain currently available solutions consider land use on a single use basis, i.e. having a single positive attribute or possible usage, because the evaluating entity or owner is not aware of the relative value of the other potential uses or does not wish to consider or value alternate or complementary uses. As a result, such solutions are inadequate in that they neither consider the entirety of the land nor examine all potential uses of the land and its natural resources. Alternately, such solutions narrowly examine market values or subjective measures.

Other solutions consider societal and economic valuations. Such solutions do not consider various factors, including but not limited to potential climate change impacts on the land and its natural resources and other factors in the realization of the overall value in full use of the land.

It would therefore to be beneficial to offer a system and method for assessing and quantifying as many potential land uses as possible and providing enhanced value to the owner of such land. Such a system and method would avoid the limitations of previous land use determination methods.

### SUMMARY OF THE INVENTION

According to one aspect of the present invention, there is provided a system for determining a set of potential land uses for at least one real property. The system comprises a processing device comprising a transmitting/receiving element configured to receive identification of the at least one real property and land use restrictions and requirements for the at least one real property and a processor configured to spatially map the at least one real property including surface and sub surface known attributes and determine potential land uses for the at least one real property based on land use restrictions and requirements for the at least one real property, and assign present values to the potential land uses. The processing device provides a number of potential land uses and assigned present values determined by the processor for the at least one real property to a requesting entity.

According to a second aspect of the present design, there is provided a method for determining a set of potential land uses for at least one real property. The method comprises receiving, at a transmitting/receiving element in a processing device, identification of the at least one real property and land use restrictions and requirements applicable to parcels of land, spatially mapping the at least one real property using a processor provided in the computing device, wherein said mapping comprises surface and sub surface known attributes of the at least one property, determining, at the processor, potential land uses for the at least one real property based on land use restrictions and requirements for the at least one real property, assigning, at the processor, present values to the potential land uses, and providing a number of potential land uses and assigned present values determined by the processor for the at least one real property to a requesting entity.

According to a third aspect of the present design, there is provided a system for determining a set of potential land uses for a land parcel. The system comprises a processing device comprising a transmitting/receiving element configured to receive attributes of the land parcel, governmental restrictions, environmental impact data, natural resource market pricing, and applicable land use restrictions and requirements for the land parcel and a processor configured to spatially map the at least one real property into a three dimensional representation including at least surface and sub-surface attributes of the land parcel, determine potential land uses for the land parcel based on available information relevant to the land parcel, and assign present values to the potential land uses. The processing device provides a number of potential land uses and assigned present values for the land parcel determined by the processor to a requesting entity.

These and other advantages of the present invention will become apparent to those skilled in the art from the following detailed description of the invention and the accompanying drawings.

### BRIEF DESCRIPTION OF THE DRAWINGS

For a more complete understanding of the present disclosure, reference is now made to the following figures, wherein like reference numbers refer to similar items throughout the figures:

FIG. 1 is a representation of the overall design;

FIG. 2 illustrates a general flowchart according to one embodiment of the present design;

FIG. 3 illustrates a parcel of land being evaluated; and

FIG. 4 shows components of the central processing device used to provide the benefits and functionality disclosed herein.

### DETAILED DESCRIPTION

The following description and the drawings illustrate specific embodiments sufficiently to enable those skilled in the art to practice the system and method described. Other embodiments may incorporate structural, logical, process and other changes. Examples merely typify possible variations. Individual elements and functions are generally optional unless explicitly required, and the sequence of operations may vary. Portions and features of some embodiments may be included in, or substituted for, those of others.

The present design includes a method and system that enhances the ability to evaluate land for numerous potential uses and provides a potential marketplace for aspects of land including natural resources available on the land. The system provides natural resource inventory layer stratification, considers and allows for legal land rights bundling, provides a level of predictive valuation, and calls for an open natural resource rights market, allowing for optimized land use or enhanced use of the value of a given tract of land.

Use of terms such as parcel, land, real property, tract, tract of land, parcel, and so forth are used interchangeably herein and are not intended to be limiting in any way.

The present design provides a computerized-implemented data system and methodology that can process multiple sources of available data. The system further provides a process for determining the relative valuation of all possible compatible means of natural resource utilization on a given tract of land or available on the tract of land currently or in the future. The system calculates, based on relative economic value, the highest and best use of the tract of land, including all its known natural resources and related bundle of rights.

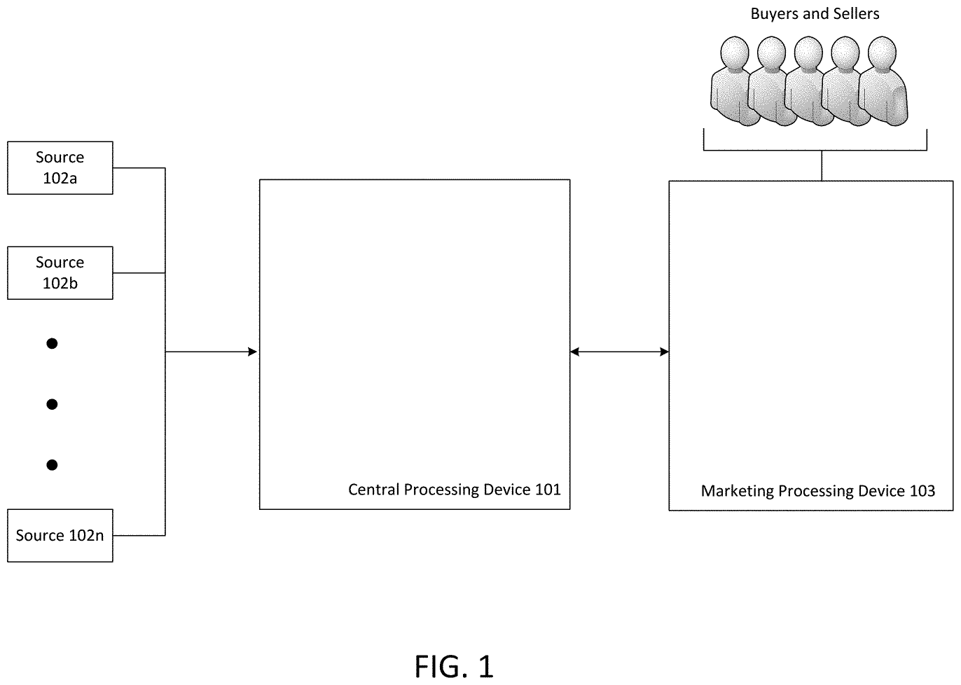

FIG. 1 is a representation of the overall design. From FIG. 1, central processing device 101, also known as a processing device, receives data from at least one source 102a-n, wherein data may include information regarding natural resources on the property, bodies of water on the property and potential use of such bodies of water (rivers, lakes, underground wells, springs, and so forth), information about existing loans and/or liens, subsurface rights and composition, potential effects of global warming over predetermined time periods, and so forth. Potential purchasers may be obtained from source(s) 102a-n, and source(s) 102a-n may include hardware devices, databases, or other sources of information. While pictured separate from central processing device 101, one or more sources 102a-n may be provided within or with central processing device 101.

Marketplace processing device 103 provides hardware for conducting a market for the property and attributes of the property, including but not limited to natural resources currently found on the parcel or tract of land. Rights and other land attributes can be auctioned, and rights can be split, such as surface rights being transferred to a third party or parties while sub-surface rights are retained. A variety of individuals may have access to marketplace processing device 103 to provide bids, provide rights and/or property and/or property attributes for sale, and administrators may administer the marketplace, and may establish rules and requirements for the marketplace and marketplace processing device.

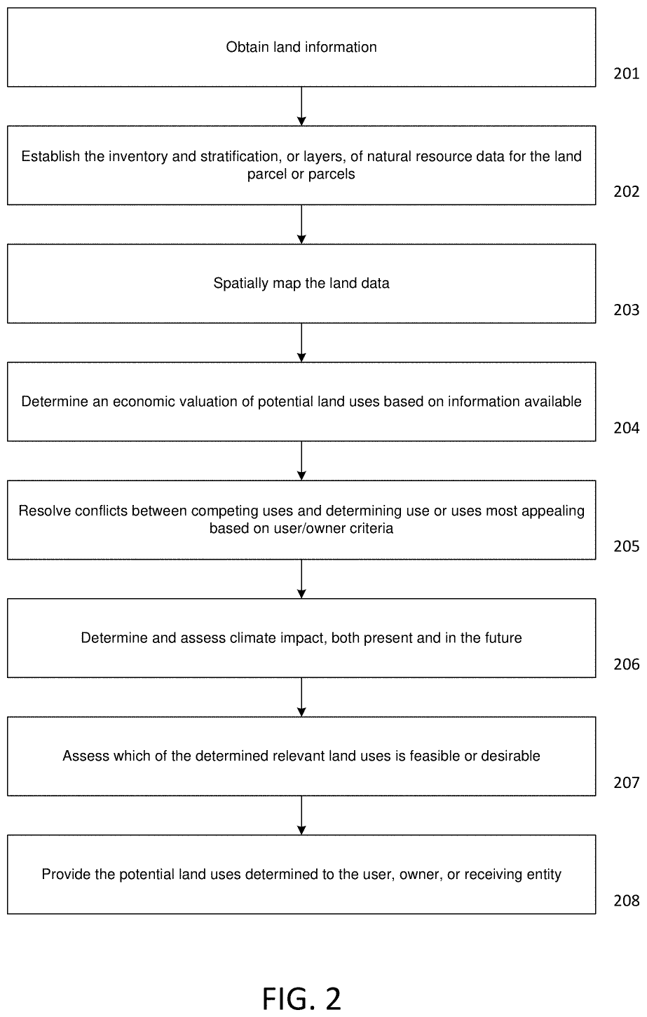

FIG. 2 is a general flowchart of the processing according to the present design. From FIG. 2, there is provided a series of processes or procedures including obtaining land information at point 201, establishing the inventory and stratification, or layers, of natural resource data for the land parcel or parcels at point 202, and spatially mapping the land data at point 203. Spatial mapping comprises forming a three dimensional representation of the entirety of the property including sub-surface and above surface attributes (geographical attributes) as appropriate. Point 204 calls for determining an economic valuation of the data based on information available. Point 204 can be divided into collecting available information about the relevant natural resources, current land values, potential for growth in the region, potential environmental issues, existing environmental issues, and so forth, using any and all available relevant information provided in the form of databases and algorithms. Point 205 calls for resolving conflicts between competing uses and determining use or uses most appealing based on user/owner criteria.

As an example, a land parcel may have minerals located thereon below the surface, and the owner may have subsurface rights to the land parcel. The system determines the cost and benefit of extracting the materials, including sale at current and potential future prices. Alternately, the parcel may be used for a commercial development, and the cost and benefit of such a development, including revenues over time, and so forth. However, use of the land as a site for commercial development would result in an inability to extract the resources for an indefinite period, while extraction of minerals may result in the land being unusable for further development. These two competing risks are weighed and both or the more preferable may be presented to the user. In a further example, the user or owner of the property may have indicated that sub-surface rights belong to another user, obviating the benefit for extracting natural resources from below the surface, or the user may have indicated a preference for constructing a structure on the land, and thus any consideration of alternate uses would be minimized Even though a user or owner may have certain preferences provided to the system, the user may be interested in all potential uses to potentially consider something he or she had overlooked or devalued.

The system therefore collects all available information usable in valuing the parcel in question, culls the information available for value that can be used or extracted both currently and in the future, makes comparison and culls valuation information not relevant to the user or owner, and presents listing of current and potential valuation for different uses of the parcel in question.

Further, the parcel can be subdivided as appropriate. The system may determine use for portions of the parcel and may provide information about, for example, the value realizable if the owner sells a particular portion of the parcel, or otherwise uses one portion of the land for one purpose and another for a different purpose.

Point 206 calls for determining and assessing climate impact, both present and in the future.

In a further example, property may have a river running through a portion. Rivers can present many use scenarios, including but not limited to extracting the water for growing crops or other uses, selling the water, fishing, creating power, and in some cases natural resources may be available from the river on a transient basis, i.e. river flow may replenish natural resources removed by the owner. However, the river may be negatively impacted by future environmental changes. In dry climates or those seeing progressively less rainfall, the river may decrease in size or dry up altogether. Thus if the owner contemplates using the river for providing water to livestock and in the future the water level decreases, becomes unusable, or dries up altogether, the value of using the land for developing livestock may decrease. The system determines and assesses other potential environmental impacts on the land in question.

The system at point 207 assesses which of the determined relevant land uses is feasible or desirable, and potentially most feasible or most desirable As an example, if the system identifies a particular party interested in acquiring rights in the region but the owner does not wish to sell to the particular party, that may be ignored. Further, certain laws and land restrictions may prohibit certain uses of land, and this may be determined either when assessing potential uses or after all potential uses have been determined to cull unavailable land use options. One example is a prohibition on raising livestock on the parcel due to zoning laws. In such a situation, use of the tract for raising cattle may be removed from potential uses. Point 207 further considers the restrictions of the owner or other entity of note.

Point 208 calls for providing the potential land uses determined to the user, owner, or receiving entity.

Based on the results determined, the system may provide selected uses to a marketplace. Offers from various systems may be provided, and a price for the applicable use disclosed. As an example, an owner may decide selling half her property at a price of SX makes financial fiscal sense considering all other uses available as determined by the system. She may list the property portion on the marketplace for SX or some other value, hoping to eventually realize SX. Alternately, iron found on a parcel may be offered at market rate on the marketplace, or even an opportunity to fish a river may be offered. Potential buyers may provide desired acquisitions to the marketplace, possibly but not necessarily including pricing details. In one scenario, a potential buyer may indicate “looking for land to develop an apartment building near main street, current value in excess of SX . . . ” Such listings may be divided by type of land use, geography, and/or search capabilities may be offered to potentially match buyers and sellers.

The system may obtain natural resource data using public information available via the internet. Laws and regulations may also be found in this manner or provided in some appropriate manner, such as via a database. Crowd sourcing of information may also be employed, wherein the system posits queries and persons can answer such queries, potentially for some form of compensation. The system can spatially map data utilizing interactive stratified layers, enabling the assessment and consideration of bundled rights utilization. The system uses data sets to value each layer based on indexes, market data and valuation methodologies. The system determines those natural resources having value and compatibility with current regulations and pricing.

The system may search large tracts of land to locate and identify areas with layers of natural resources and related rights data to maximize realized economic value and further minimize climate change impacts. The marketplace provides an open online bid/offer public forum for assessment and potential sale of stratified natural resource rights and the resources themselves.

The system as discussed may account for time and future values in making a land use assessment. Time based effects such as erosion, fluctuations in currencies and values over time, inflation, and so forth may be obtained and/or provided to or by the system.

The present system may be employed to search property or properties for particular beneficial attributes based on requirements provided. For example, if a user is interested in properties that have a particular natural resource available, the system may

The marketplace provides search capability across the land evaluated and natural resource data. The system can identify natural resource data sets that match a user search based on characteristics and valuations. The system may modify existing information as new information becomes available or is determined.

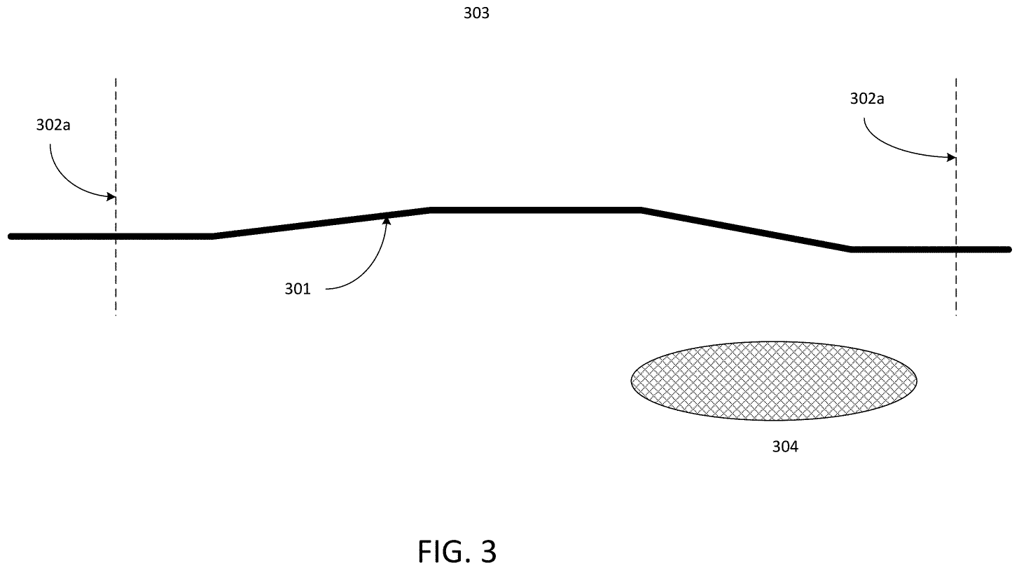

FIG. 3 shows a representative parcel of land. The system may create a three dimensional spatial map of the parcel including the various attributes, while the FIG. 3 representation is two dimensional. A three dimensional construction or representation may indicate natural resources on part of the property, at a particular depth, with no such resources at another part of the property at a similar or different depth. Such three dimensional modeling may provide information as to how the area may be employed, i.e. excavation practical and available at region P but not region Q. With respect to the land surface 301, having boundaries 302a and 302b, such land may be used for any conceivable and practical purpose, including but not limited to placing a structure or structures thereon, commercial and/or residential, building a road, park, or other facility, use for farming, and so forth. Assuming the parcel is held in fee simple absolute, including above ground rights, rights above the land surface 301, shown as region 303, could be used. For example, a zip line could be constructed over the property for personal or commercial use. Subsurface rights may include rights to oil, underground water, minerals, or anything existing or buildable below the surface, such as underground garages or tunnels. In FIG. 3, shale deposit region 304 is shown.

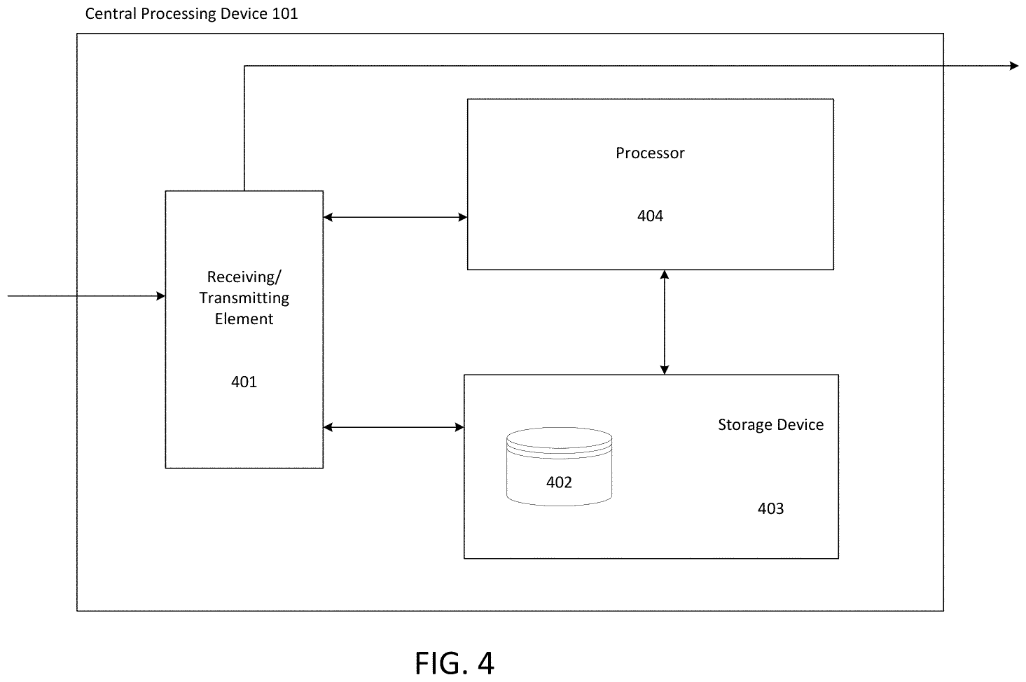

FIG. 4 shows a representation of central processing device 101, wherein receiving/transmitting element 401 receives information and may be employed to seek additional information such as by exploring the internet for data, changes in data, or other information. Database 402 in storage device 403 is a database that locally maintains relevant information in various categories, such as government regulations by jurisdiction, predictive considerations such as currency, weather, and climate predictions for various regions, potential land uses, natural resource information and pricing, and so forth. Storage device 403 may be any type of storage device, including a hard disk drive, and may include multiple components, such as multiple hard drives or storage units. The database 402 may be updated continuously or periodically when new information is available. Also provided in storage device 403 are algorithms used for prediction, determining of land uses, and so forth. Processor 404 obtains relevant algorithms and/or data from storage device 403 and makes the determinations noted herein and may provide results to the user or to the marketplace or to any appropriate computing device via receiving/transmitting element 401. While shown as particular devices in FIG. 4, it is to be understood that any computing device components able to or configured to perform the functionality herein may be employed, and the invention is not limited by the depictions provided herein.

The system takes the information about the property and may initially receive restrictions on use from an appropriate entity, such as the owner or user. For example, the property cannot be sold to a real estate investment trust, the property is not to be subdivided, and no roads are to be constructed on the property. The system may then, using any restrictions established, investigate applicable legal attributes of the property, such as current owner, restrictions on use (local, city, state, federal), taxes, potential taxes based on use, and so forth. Such an investigation may be altered based on the restrictions initially provided. For example, if the property is not to be subdivided, no inquiry as to local, state, or federal rules on subdividing parcels would be necessary and the system would not perform such searches, inquiries, evaluations, or assessments.

The system may then assess attributes of the property, size, current market value, rights, subsurface rights, subsurface soil or mineral content and makeup, geographical features, and so forth. The system may also or alternately obtain or receive restrictions as to removal of natural resources on the property, and other related restrictions on use of the land. For example, if the land may contain oil but the existence of oil has not been demonstrated, but all subsurface rights are provided to a prior owner, the system will not consider the possible removal of any oil from the property.

Based on the parcel of land, including location, size, geographical features, etc., the system may search for various uses in various categories, including use as a property for sale of all or part of the tract, use of the property for development (residential or commercial), use of natural resources available on the land, leasing of the land for particular purposes, and a general assessment of uses the land can be put to based on available information. The system may cause an interaction with the marketplace system wherein the marketplace system is consulted as to available offers or requests for particular land uses, restrictions of such offers, and whether the current property may or would satisfy the buyer criteria.

Based on the entirety of the foregoing, the system may assess and determine all logical and available potential uses and may quantify, in terms of current and/or future revenues, price fluctuations for market values, and so forth, a collection of potential uses for the land. The system may then provide all logical and reasonable potential uses to the user and/or seller.

Alternately, the system may simply receive an inquiry, from an entity or from the marketplace, for a particular land use of interest, and the system may search for such a property and provide a listing of potential properties to the entity or potential buyer if any can be determined and/or are available. Criteria provided to the processing hardware of FIG. 1 may be parsed and global available properties according to the requirements identified. As an example, the marketplace may receive a request for a property at least 50 acres in size that has existing or potential quartz located thereon, with no zoning or governmental restrictions on excavation, and with a quartz processing facility within a two hour drive, in any country in the Western hemisphere, the system may search known properties that fit the description and identify candidate properties to the potential marketplace buyer.

Thus the present system provides a means for identifying a parcel of land and gathering relevant information relating to the parcel of land including owner restrictions, use restrictions, governmental regulations, market data, resource pricing, etc. The system may seek information from existing data or databases, such as information maintained locally or on publicly available data sites, such as on the internet, and may use alternate techniques such as crowdsourcing to obtain relevant potential use information. Based on all available information, restrictions, etc., the system may determine potential available land uses for the parcel and provide such uses and the value of such uses to the user or owner. Different categories of uses may be considered, including but not limited to surface uses (construction, farming, etc.), subsurface/natural resource uses, potential sale uses, and so forth. The result is a list of potential uses and in one embodiment present day values of such uses at market rates. Aspects such as global environmental impact may be considered as well as future conditions such as market and currency changes, etc.

The system may include a marketplace or marketplace hardware that provides a land use buying and selling market for land uses identified. The market may list available properties and potential uses as well as desired conditions for the acquisition of land based on anticipated use, and such queries may be assessed by the system and potential candidate tracts identified potentially anywhere on the globe.

According to one aspect of the present invention, there is provided a system for determining a set of potential land uses for at least one real property. The system comprises a processing device comprising a transmitting/receiving element configured to receive identification of the at least one real property and land use restrictions and requirements for the at least one real property and a processor configured to spatially map the at least one real property including surface and sub surface known attributes and determine potential land uses for the at least one real property based on land use restrictions and requirements for the at least one real property, and assign present values to the potential land uses. The processing device provides a number of potential land uses and assigned present values determined by the processor for the at least one real property to a requesting entity.

According to a second aspect of the present design, there is provided a method for determining a set of potential land uses for at least one real property. The method comprises receiving, at a transmitting/receiving element in a processing device, identification of the at least one real property and land use restrictions and requirements applicable to parcels of land, spatially mapping the at least one real property using a processor provided in the computing device, wherein said mapping comprises surface and sub surface known attributes of the at least one property, determining, at the processor, potential land uses for the at least one real property based on land use restrictions and requirements for the at least one real property, assigning, at the processor, present values to the potential land uses, and providing a number of potential land uses and assigned present values determined by the processor for the at least one real property to a requesting entity.

According to a third aspect of the present design, there is provided a system for determining a set of potential land uses for a land parcel. The system comprises a processing device comprising a transmitting/receiving element configured to receive attributes of the land parcel, governmental restrictions, environmental impact data, natural resource market pricing, and applicable land use restrictions and requirements for the land parcel and a processor configured to spatially map the at least one real property into a three dimensional representation including at least surface and sub-surface attributes of the land parcel, determine potential land uses for the land parcel based on available information relevant to the land parcel, and assign present values to the potential land uses. The processing device provides a number of potential land uses and assigned present values for the land parcel determined by the processor to a requesting entity.

The foregoing description of specific embodiments reveals the general nature of the disclosure sufficiently that others can, by applying current knowledge, readily modify and/or adapt the system and method for various applications without departing from the general concept. Therefore, such adaptations and modifications are within the meaning and range of equivalents of the disclosed embodiments. The phraseology or terminology employed herein is for the purpose of description and not of limitation.

What is claimed is:

1. A system for determining a set of potential land uses for at least one real property, comprising:
a processing device, comprising:
a transmitting/receiving element configured to receive identification of the at least one real property and land use restrictions and requirements for the at least one real property; and
a processor configured to spatially map the at least one real property including surface and sub surface known attributes and determine potential land uses for the at least one real property based on land use restrictions and requirements for the at least one real property, and assign present values to the potential land uses;
wherein the processing device provides a number of potential land uses and assigned present values determined by the processor for the at least one real property to a requesting entity.

2. The system of claim 1, further comprising a marketplace processing device that receives real property information and land use information and is configured to match buyers with sellers of real property land uses.

3. The system of claim 1, wherein the processor develops a three dimensional spatial map of the at least one real property.

4. The system of claim 1, wherein the transmitting/receiving element is configured to receive electronic land use solicitations and the processor is configured to search for properties conforming to the electronic land use solicitations.

5. The system of claim 1, wherein land uses considered by the processor for the at least one real property comprise extraction of natural resources from the at least one real property.

6. The system of claim 1, wherein the transmitting/receiving element receives environmental impact data and the processor is configured to determine land uses based on environmental impact data.

7. The system of claim 2, wherein the marketplace processing device provides land use offers to the processing device and the processor determines any parcels conforming to each land use offer provided.

8. A method for determining a set of potential land uses for at least one real property, comprising:
receiving, at a transmitting/receiving element in a processing device, identification of the at least one real property and land use restrictions and requirements applicable to parcels of land;
spatially mapping the at least one real property using a processor provided in the computing device, wherein said mapping comprises surface and sub surface known attributes of the at least one property;
determining, at the processor, potential land uses for the at least one real property based on land use restrictions and requirements for the at least one real property;
assigning, at the processor, present values to the potential land uses; and
providing a number of potential land uses and assigned present values determined by the processor for the at least one real property to a requesting entity.

9. The method of claim 8, further comprising:
receiving real property information and land use information a marketplace processing device; and
matching buyers with sellers of real property land uses at the marketplace processing device.

10. The method of claim 8, further comprising determining a three dimensional spatial map of the at least one real property at the processor, wherein the processor determines available land uses for all surface, below surface, and above surface attributes of the at least one real property.

11. The method of claim 8, further comprising receiving electronic land use solicitations at the transmitting/receiving device and searching for properties conforming to the electronic land use solicitations at the processor.

12. The method of claim 8, wherein land uses considered by the processor for the at least one real property comprise extraction of natural resources from the at least one real property.

13. The method of claim 8, further comprising receiving environmental impact data at the transmitting/receiving device and determining land uses based on environmental impact data at the processor.

14. The method of claim 9, further comprising providing land use offers from the marketplace processing device to the processing device and determining any parcels conforming to each land use offer provided using the processor.

15. A system for determining a set of potential land uses for a land parcel, comprising:
a processing device, comprising:
a transmitting/receiving element configured to receive attributes of the land parcel, governmental restrictions, environmental impact data, natural resource market pricing, and applicable land use restrictions and requirements for the land parcel; and
a processor configured to spatially map the at least one real property into a three dimensional representation including at least surface and sub-surface attributes of the land parcel, determine potential land uses for the land parcel based on available information relevant to the land parcel, and assign present values to the potential land uses;
wherein the processing device provides a number of potential land uses and assigned present values for the land parcel determined by the processor to a requesting entity.

16. The system of claim 15, further comprising a marketplace processing device that receives real property information and land use information and is configured to match buyers with sellers of real property land uses.

17. The system of claim 15, wherein the transmitting/receiving element is configured to receive electronic land use solicitations and the processor is configured to search for properties conforming to the electronic land use solicitations.

18. The system of claim 16, wherein the marketplace processing device provides land use offers to the processing device and the processor determines any parcels conforming to each land use offer provided.
